(19) United States
(12) Patent Application Publication
(10) Pub. No.: US 2004/0189326 A1
(43) Pub. Date: Sep. 30, 2004

(54) Vector-detecting apparatus and impedance measuring apparatus

(75) Inventor: Kiyoshi Chikamatsu, Kanagawa (JP)

Correspondence Address: Paul D. Greeley, Esq., Ohlandt, Greeley, Ruggiero & Perle, L.L.P., One Landmark Square, 10th Floor, Stamford, CT, 06901-2682, US

(73) Assignee: AGILENT TECHNOLOGIES, INC.

(21) Appl. No.: 10/809,297

(22) Filed: Mar. 25, 2004

(30) Foreign Application Priority Data
Mar. 27, 2003 (JP) 2003-087144

(51) Int. Cl. G01R 27/28; H02P 5/28

(52) U.S. Cl. 324/650

(57) ABSTRACT

The vector-detecting apparatus of an impedance measuring apparatus comprising a signal source, an automatic balanced bridge, and a vector-detecting apparatus comprises a first and a second filter, whose impulse responses are weighted by a sine function and a cosine function, and the vector of the signals input to the vector-detecting apparatus is determined using the first and second filters. Moreover, the frequency of the signals input to the frequency converter is an integer multiple of the frequency of the signals output from the frequency converter when the input signals are frequency-converted at the step before the vector-detecting apparatus.

### BACKGROUND OF THE INVENTION

1. Field of the Invention

The present invention pertains to a vector-detecting apparatus and relates in particular to a vector-detecting apparatus with which high-speed detection is possible. The vector-detecting apparatus of the present invention is preferably used in impedance measuring apparatuses, and the like.

2. Discussion of the Background Art

Apparatuses that operate by the automatic balanced bridge method are an example of the prior art of impedance measuring apparatuses. Impedance measuring apparatuses that operate by the automatic balanced bridge method are characterized in that they cover a broad measurement frequency range and their measurement accuracy is good within a broad impedance measurement range.

The general structure and operation of an impedance measuring apparatus that operates by the automatic balanced bridge method are described below. The general structure of an impedance apparatus that operates by the automatic balanced bridge method is shown in FIG. 1. In FIG. 1, the impedance measuring apparatus 100 comprises a signal source 200, an automatic balanced bridge 300, and a vector ratio determining apparatus 500.

Signal source 200 is the signal source that generates the measurement signals applied to device under test 400.

Automatic balanced bridge 300 is a device that outputs a voltage signal E_{dut} applied to device under test 400 and outputs a voltage signal Eᵣᵣ converted from the current that flows to device under test 400. Automatic balanced bridge 300 comprises as its structural elements a measurement electrode High and a measurement electrode Low for connecting the device under test 400, and a current-to-voltage transformer 310 which includes an input terminal imaginary grounded and connected to device under test 400. Current-to-voltage transformer 310 converts the current signals that are output from device under test 400 to voltage signals and thereafter outputs the signals.

Vector ratio-determining device 500 is a device that determines the vector ratio of voltage signal E_{dut} and voltage signal Eᵣᵣ. Vector ratio-determining device 500 comprises as its structural elements buffer amps 510, 511, 512, and 513, a switch 520, a mixer 530, a local oscillator 540, a low-pass filter 550, an analog-digital converter 560, a digital signal processor 570, and a CPU 580. Hereafter analog-digital converters are referred to as A/D converters and digital signal processors are referred to as DSP. Switch 520 comprises two input terminals and one output terminal and selects and outputs one of the two input signals. Switch 520 is switched as needed under the control of CPU 580. The two voltage signals that are output from automatic balanced bridge 300 are input to switch 520 through a buffer amp. In detail, voltage signal E_{dut} is input to one input terminal of switch 520 through buffer amp 510. Moreover, voltage signal Eᵣᵣ is input to the other input terminal of switch 520 through buffer amp 511. The signal that has been selected by switch 520 is input to mixer 530 through buffer amp 512.

Mixer 530 multiplies the signal output from switch 520 with the signal output from local oscillator 540. This multiplication of signals having different frequencies each other causes heterodyne frequency conversion. When the frequencies of two signals input to mixer 530 are regarded as f_{A} and f_{B}, the output signal of mixer 530 ideally contains spectrum having the sum frequency (f_{A}+f_{B}) and spectrum having the difference frequency (f_{A}−f_{B}). Of these output spectral, spectrum having the difference frequency is measured as the signal under test. In reality, voltage signal E_{dut} and voltage signal Eᵣᵣ that are input to mixer 530 and output signal of local oscillator 540 comprise of undesired frequency components other than the fundamental frequency. Consequently, the output signal of mixer 530 comprises even more undesired frequency components. These undesired frequency components affect the determination results and therefore should be blocked by low-pass filter 550.

Signals under test are input to A/D converter 560 through low-pass filter 550 and buffer amp 513. Low-pass filter 550 has frequency characteristics such that it also functions as an anti-alias filter for A/D converter 560. A/D converter 560 samples input signals at sampling frequency fₛ. DSP 570 determines the vector of the signals under test. Specifically, DSP 570 performs fast Fourier transform of signal data that have been sampled by A/D converter 560 and determines the in-phase component and the quadrature-phase component of the signal under test. Fast Fourier transform is hereafter referred to as FFT. DSP 570 determines the in-phase component and the quadrature-phase component of the signal under test when voltage signal E_{dut} has been selected and determines the in-phase component and the quadrature-phase component of the signal under test when voltage signal Eᵣᵣ has been selected as a result of switching switch 520. CPU 580 determines the vector ratio of voltage signal E_{dut} and voltage signal Eᵣᵣ from this in-phase component and the quadrature-phase component.

Signal source 200 and local oscillator 540 are controlled by CPU 580 so that their frequency difference of the output signals becomes the frequency of the signal under test. Consequently, the oscillation frequency of local oscillator 540 changes in accordance with the frequency of the measurement signals that are applied to device under test 400.

Impedance measuring device 100 has the structure described above and therefore, the impedance of device under test 400 can be measured from the vector ratio of voltage signal E_{dut} and voltage signal Eᵣᵣ and known resistances of converting resistors that current-to-voltage transformer 310 comprises.

Conventional impedance measuring apparatus 100 has two problems with high-speed measurement. The first problem is the settling time of transient phenomena that are caused as a response of the output signals of low-pass filter 500 immediately after switch 520 is switched. These transient phenomena affect the measurement results and therefore, impedance measuring device 100 must wait before starting measurements until these transient phenomena have settled.

The transient phenomena settling time is closely related to the inverse of the cut-off frequency f_{c} of low-pass filter 550. Moreover, cut-off frequency f_{c} of low-pass filter 550 is set in accordance with frequency of the output signals of filter 540, that is, frequency f_{IF} of the signal under test. For instance, if frequency fₘ of the measurement signal is set at 30 kHz and frequency f_{LO} of the output signal of local oscillator 540 is set at 31 kHz, frequency f_{IF} of the signal under test by impedance measuring apparatus 100 will be 1 kHz. As previously mentioned, the output signals of mixer 540 include unwanted signals other than the signals under test. Low-pass filter 550 sets this cut-off frequency f_{c} so that these unwanted signals are cut off. One typical unwanted signal included in the output signals of mixer 540 is a feed-through component, such as fₘ or f_{LO}. This feed-through component badly affects measurement results. The feed-through component must be attenuated to −120 dBc in order to be able to disregard the effect on the measurement results. On the other hand, attenuating the signal under test should be avoided as much as possible. When the feed-through component comprising the output signals of mixer 540 is −60 dBc, low-pass filter 550 may be a Butterworth filter of order 6 or higher with a cut-off frequency f_{c} of 3 kHz in order to simultaneously satisfy these requirements. In this case, the transient phenomena will persist for a time constant τ=0.3 millisecond in the output signals of low-pass filter 550 immediately after switching switch 520. The settling time of transient phenomena is usually set at ten times the transient time constant τ. Consequently, impedance measuring apparatus 100 must wait three milliseconds after switching switch 520 before beginning measurements.

Frequency f_{IF} and therefore cut-off frequency f_{c} can be increased in order to shorten this settling time. For instance, if frequency f_{LO} is set at 39 kHz, frequency f_{IF} becomes 9 kHz and cut-off frequency f_{c} becomes 27 kHz. Moreover, the settling time becomes approximately 0.3 millisecond. In this case as well, it is necessary to attenuate the feed-through component to −120 dBc in order to be able to disregard the effect of the feed-through component on the measurement results, as previously mentioned. However, the feed-through component frequency fₘ and the cut-off frequency f_{c} are close to one another and therefore, low-pass filter 550 must be a filter with a very sharp attenuation slope. When low-pass filter 550 comprises a Butterworth filter, the order of the filter that is needed is very high and the filter is impractical. Moreover, if low-pass filter 550 comprises a Chebychev filter, problems with measurement error will newly arise in the frequency characteristics of the filter, such as passband ripple, will be fluctuated due to circuit element variations, and the measurement results will have large distributions, and the like.

The second problem is the FFT operation time. FFT of 4m point data requires (16m log₂4m) calculations, where m is a natural number. For instance, when m=2, 96 calculations are necessary. Even though there has been a considerable increase in the processing capability of digital signal processors in recent years, the calculation time for FFT operation is still a hindrance to high-speed measurement.

The formation of thin films has advanced to such a point that the thickness of MOS device gate oxide films is less than 2 nm as a result of the progress that has been made in recent years in semiconductor microfabrication technology in accordance with Moore's law. This gate oxide film thickness is an important parameter that determines the operating threshold of MOS devices and therefore, the exact in-wafer distribution of the oxide film thickness must be measured at a high through-put in MOS device wafer production processes. Though destructive methods can be used for this oxide film thickness measurement, such as cross section observation using a transmission electron microscope, in most cases the film thickness is estimated by the measurement of MOS capacitance and calculation of equivalent thickness assuming the dielectric constant. When the MOS capacitance is measured today, a very small capacitance of 10 pF should be measured at an accuracy of 0.1% in 1 millisecond or less. Consequently, high-accuracy, high-speed measurement of capacitance is extremely important in the semiconductor industry.

### SUMMARY OF THE INVENTION

The present invention realizes high-speed measurement by impedance measuring apparatuses without deterioration of measurement accuracy.

Moreover, the present invention is an impedance measuring apparatus comprising a vector-detecting apparatus, with this vector-detecting apparatus comprising a first filter and a second filter whose impulse responses are orthogonal to each other and the output of the first filter serving as the in-phase component of the pre-determined frequency signal and the output of the second filter serving as the quadrature-phase component of the pre-determined frequency signal. Moreover, when the input signal is frequency-converted at the step before the vector-detecting apparatus, the ratio of the frequency before this conversion and the frequency after this conversion becomes an integer of 2 or higher.

### BRIEF DESCRIPTION OF THE DRAWINGS

FIG. 1 is a schematic drawing of the structure of an impedance measuring apparatus of the prior art.

FIG. 2 is a schematic drawing of the structure of an impedance measuring apparatus of the technology of the present invention.

FIG. 3A is a drawing showing the internal block of filter 860.

FIG. 3B is a drawing showing the internal block of filter 865.

FIG. 4 is a drawing showing the frequency-attenuation characteristic of filter 860 and filter 865.

FIG. 5 is a drawing showing the spectrum of the output signals of mixer 530.

FIG. 6 is a drawing showing the spectrum of the output signals of mixer 530.

FIG. 7A is a drawing showing the internal block of filter 870.

FIG. 7B is a drawing showing the internal block of filter 875.

FIG. 8 is a drawing showing the frequency-attenuation characteristic of filter 870 and filter 875.

FIG. 9A is a drawing showing the internal block of filter 880.

FIG. 9B is a drawing showing the internal block of filter 885.

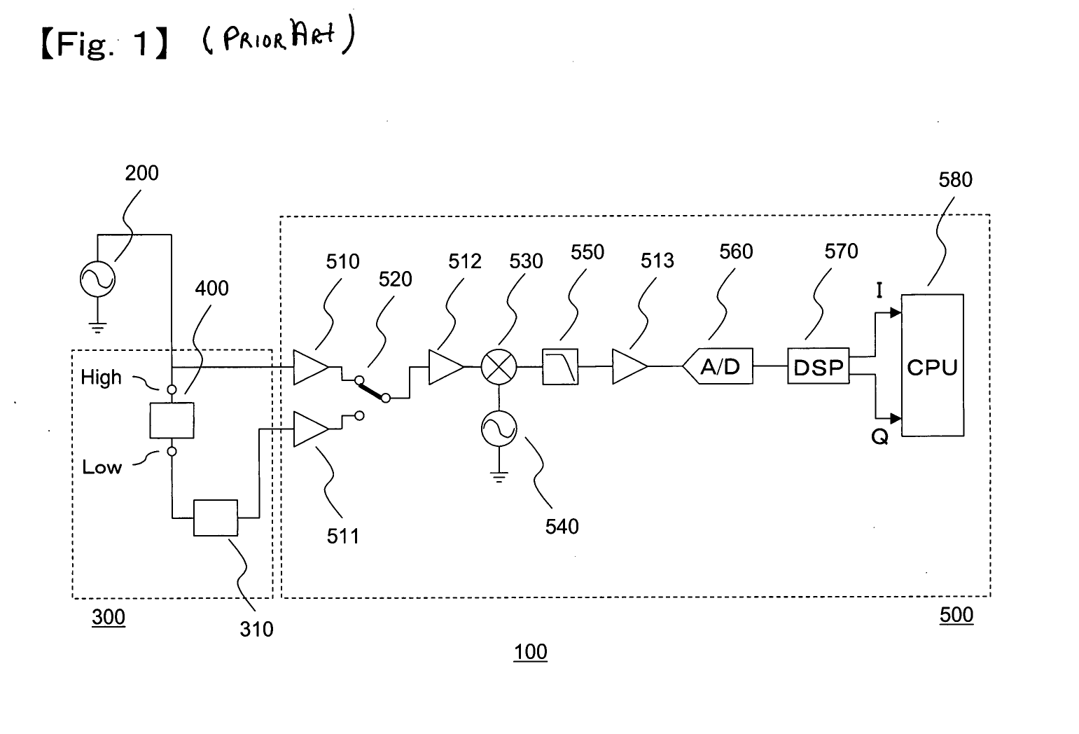

### DETAILED DESCRIPTION OF THE PREFERRED EMBODIMENTS

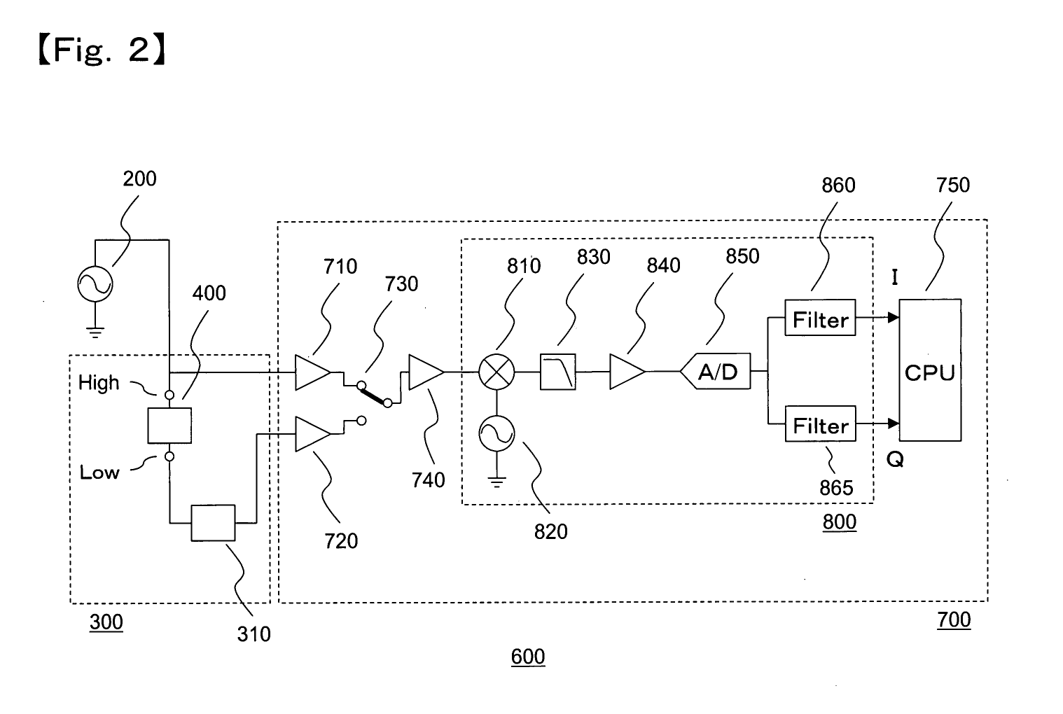

The present invention will now be described based on the preferred embodiments shown in the appended drawings. The first embodiment of the present invention is an impedance measuring apparatus that operates by the automatic balanced bridge method and a schematic drawing of its structure is shown in FIG. 2.

An impedance measuring apparatus 600 in FIG. 2 comprises a signal source 200, an automatic balanced bridge 300, and vector ratio-determining device 700.

Signal source 200 is the signal source that generates measurement signals applied to a device under test 400. The measurement signals are sine-wave signals of frequency fₘ.

Automatic balanced bridge 300 is a device that outputs a voltage signal E_{dut} that is applied to device under test 400 and voltage signals Err that are converted from the current that flows to device under test 400. Automatic balanced bridge 300 comprises as its structural elements of a measurement electrode High and a measurement electrode Low for connecting the device under test 400, a current-to-voltage transformer 310 has an input terminal grounded and connected to device under test 400. Current-to-voltage transformer 310 converts the current signals that are output from device under test 400 to voltage signals and thereafter output the signals.

Vector ratio-determining device 700 is a device that determines the vector ratio between voltage signal E_{dut} and voltage signal Eᵣᵣ. Vector ratio-determining device 700 comprises as its structural elements buffer amps 710, 720, and 740, a switch 730, a vector-detecting apparatus 800, and a CPU 750.

Switch 730 comprises two input terminals and one output terminal and selects and outputs one of two input signals. Switch 520 is switched as needed under the control of CPU 750. Two voltage signals are output from automatic balanced bridge 300 and are input through buffer amps to switch 730. In detail, voltage signal E_{dut} is input through buffer amp 710 to one input terminal of switch 730. Moreover, voltage signal Eᵣᵣ is input through buffer amp 720 to the other input terminal of switch 730. The signal selected by switch 730 is input through buffer amp 740 to mixer 810.

Vector-detecting apparatus 800 is an apparatus that detects the vector of an input signal and comprises a mixer 810, a local oscillator 820, a low-pass filter 830, a buffer amp 840, an analog-digital converter 850, and filters 860 and 865. Analog-digital converter 850 is hereafter referred to as A/D converter 850. Mixer 810 multiplies signals that are output from switch 730 and signals that are output from local oscillator 820 and outputs the multiplied signals. The output signals of local oscillator 820 are sine-wave signals of frequency f_{LO}. Of the output spectral from mixer 810, spectrum having different frequency are measured as the signal under test. Moreover, frequency f_{IF} of the signals under test is set so that the relationship in the following formula is established.

$${f}_{IF} = \frac{1}{N} {{f}_{\text{?}}}_{\text{?}} = \frac{1}{N + 1} {{f}_{\text{?}}}_{\text{?}}$$

$$\text{?} \text{indicates text missing or illegible when filed}$$

N is an integer of 2 or higher. The output signals of mixer 810 are input through low-pass filter 830 and buffer amp 840 to A/D converter 850. A/D converter 850 samples the input signals at a sampling frequency fₛ. Sampling frequency fₛ is a frequency that is the 4m multiple of the frequency f_{IF} of the signal under test. Moreover, the cut-off frequency f_{c} of low-pass filter 550 is set so that it can also function as the anti-alias filter for A/D converter 560.

$${f}_{s} \text{?} \text{?} 4 m \cdot {f}_{IF}$$

$${f}_{s} \leq \frac{1}{2} {f}_{s}$$

$$\text{?} \text{indicates text missing or illegible when filed}$$

m is a natural number. Sampled signal data V(n) are processed by filter 860 and filter 865 and output.

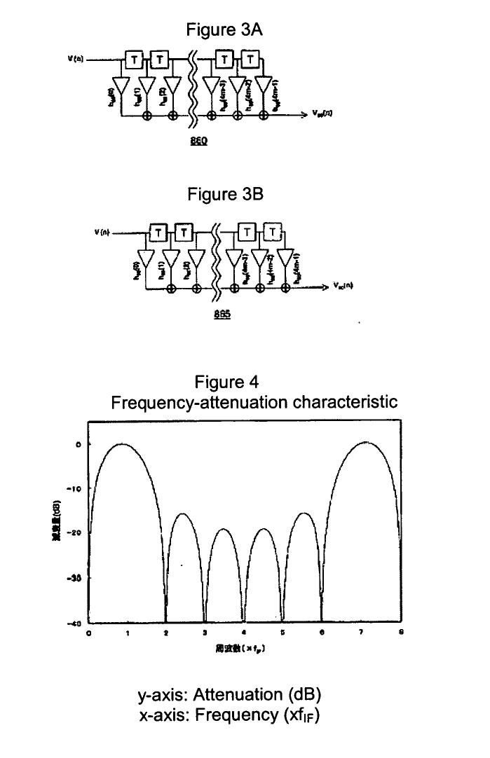

Filter 860 and filter 865 are linear FIR digital filters. The inside block of filter 860 and filter 865 is shown in FIG. 3A and FIG. 3B. T in FIG. 3A and FIG. 3B is the time delay that is equal to the inverse of sampling frequency fₛ. Filter 860 and filter 865 have response characteristics represented by the following formulas based on the effect of filter coefficients hₒₒ(k) and h₉₀(k).

$${V}_{oo} ( n ) = {\sum }_{k = 0}^{4 m - 1} {h}_{oo} ( k ) \cdot V ( n - k )$$

$${V}_{90} ( n ) = {\sum }_{k = 0}^{4 m - 1} {h}_{90} ( k ) \cdot V ( n - k )$$

$$Here , \\ {h}_{oo} ( k ) = \frac{sin ( \frac{π}{2 m} k + θ )}{2 m}$$

$${h}_{90} ( k ) = \frac{cos ( \frac{π}{2 m} k + θ )}{2 m}$$

θ is any value.

Filter 860 and filter 865 have the same frequency-attenuation characteristic. The frequency-attenuation characteristic of filter 860 and filter 865 when m=2 is shown in FIG. 4. The y-axis in FIG. 4 shows the attenuation of filter 860 and filter 865 and the x-axis shows the frequency normalized at frequency f_{IF} of the signal under test. According to FIG. 4, filter 860 and filter 865 have an obvious attenuation characteristic near the frequency that corresponds to the higher harmonics component of the signal under test. Filter 860 and filter 865 have an obvious attenuation characteristic near the frequency that corresponds to the higher harmonics component of the signal under test even in cases other than m=2.

Next, the spectrum of the output signals of mixer 810, the frequency-attenuation characteristic of low-pass filter 830, and the frequency-attenuation characteristic of filter 860 and filter 865 are shown in FIG. 5.

The spectrum of the output signals of mixer 810 is given under the following conditions. First, the terminal in mixer 810 that inputs voltage signal E_{dut} and voltage signal Eᵣᵣ is regarded as the RF terminal, the terminal that inputs the output signal of local oscillator 820 is regarded as the LO terminal, and the output terminal is regarded as the IF terminal. The isolation between the RF terminal and the IF terminal of mixer 810 is 60 dB and the isolation between the LO terminal and the IF terminal of mixer 810 is 46 dB. The frequency of voltage signal E_{dut} and voltage signal Eᵣᵣ,that is, frequency fₘ of the measurement signal, is set at 30 kHz. Frequency f_{LO} of the output signals of local oscillator 820 is set at 40 kHz. Moreover, voltage signal E_{dut} and/or voltage signal Eᵣᵣ, as well as the output signal of local oscillator 820, may contain second, third, fifth, and seventh order harmonics. The second order harmonic is regarded as −60 dBc and the third through seventh orders are each regarded as −70 dBc. Furthermore, the cut-off frequency f_{c} of low-pass filter 830 is regarded as 40 kHz.

The dotted curves in FIG. 5 shows the frequency-attenuation characteristic of filter 860 and filter 865. Moreover, the dashed curve in FIG. 5 shows the frequency-attenuation characteristic of low-pass filter 830. The vertical solid lines in FIG. 5 show the spectrum of the output signal of mixer 810. The spectrum of the output signal of mixer 810 is normalized by frequency f_{IF} of the signal under test and the amplitude at the frequency f_{IF}. The y-axis on the left side in FIG. 5 shows the signal spectrum, the y-axis on the right side shows the attenuation, and the x-axis shows the frequency normalized by frequency f_{IF} of the signal under test. Frequency f_{IF} of the signal under test is set so that it becomes 1/N of frequency fₘ of the measurement signal and therefore, in addition to the frequency (f_{IF}) component of the signal under test, the output signal of mixer 810 contains signal components that are present in the higher harmonic frequencies of the signal under test. Signal components that are present in the higher harmonic frequencies of the signal under test have an effect on the measurement results and therefore are unnecessary. It is clear from FIG. 5 that these undesired signal components are attenuated considerably by filter 860 or filter 865. When m=2, filter 860 or filter 865 has a low attenuating effect near 7f_{IF}. However, frequency components of at least 4f_{IF} or higher are cut off by low-pass filter 830, which is an anti-alias filter, and therefore, in the end even the components near 7f_{IF} are attenuated.

Next, a table relating to measurement error is shown in Table 1. It shows the output signals of mixer 810, the attenuation of low-pass filter 830, the attenuation of filter 860 and filter 865, and the measurement error. Error 1 is the measurement error when the output signal of mixer 810 has been filtered by filter 860 or filter 865. Moreover, error 2 is the measurement error when the output signal of mixer 810 has been filtered by low-pass filter 830, as well as filter 860 or filter 865.

TABLE 1

| | | | | Low-pass filter | Filter 860 | | |
|---|---|---|---|---|---|---|---|
| Mixer 810 | | | | 830 (fc = 40 kHz) | Filter 865 | | |
| | Frequency | Ratio to | Output | Attenuation | Attenuation | Error 1 | Error 2 |
| Component | (kHz) | f_{IF} | (dBc) | (dB) | (dB) | (ppm) | (ppm) |
| f_{LO} − fₙ = f_{IF} | 10.00 | 1.00 | 0.00 | 0.00 | 0.00 | | |
| 3fₙ − 2f_{LO} | 10.00 | 1.00 | −130.00 | 0.00 | 0.00 | 0.32 | 0.32 |
| 7fₙ − 5f_{LO} | 10.00 | 1.00 | −140.00 | 0.00 | 0.00 | 0.10 | 0.10 |
| 2f_{LO} − 2fₙ | 20.00 | 2.00 | −120.00 | 0.00 | −317.72 | 0.00 | 0.00 |
| 2fₙ − f_{LO} | 20.00 | 2.00 | −60.00 | 0.00 | −317.72 | 0.00 | 0.00 |
| 3f_{LO} − 3fₙ | 30.00 | 3.00 | −140.00 | −0.27 | −359.15 | 0.00 | 0.00 |
| fₙ | 30.00 | 3.00 | −54.00 | −0.27 | −353.15 | 0.00 | 0.00 |
| 5fₙ − 3f_{LO} | 30.00 | 3.00 | −140.00 | −0.27 | −353.15 | 0.00 | 0.00 |
| f_{LO} | 40.00 | 4.00 | −40.00 | −6.02 | −318.42 | 0.00 | 0.00 |
| 5f_{LO} − 5fₙ | 50.00 | 5.00 | −140.00 | −23.84 | −353.15 | 0.00 | 0.00 |
| 2f_{LO} − fₙ | 50.00 | 5.00 | −80.00 | −23.84 | −353.15 | 0.00 | 0.00 |
| 3fₙ − f_{LO} | 50.00 | 5.00 | −70.00 | −23.84 | −353.15 | 0.00 | 0.00 |
| 3f_{LO} − 2fₙ | 60.00 | 6.00 | −130.00 | −42.33 | −317.72 | 0.00 | 0.00 |
| 2fₙ | 60.00 | 6.00 | −114.00 | −42.33 | −317.72 | 0.00 | 0.00 |
| 7f_{LO} − 7fₙ | 70.00 | 7.00 | −140.00 | −58.34 | 0.00 | 0.10 | 0.00 |
| 5fₙ − 2f_{LO} | 70.00 | 7.00 | −130.00 | −58.34 | 0.00 | 0.32 | 0.00 |

| | | | |
|---|---|---|---|
| Total error (ppm) | [symbol] (ppm) | 0.83 | 0.42 |
| Total error (%) | [symbol] (%) | 0.0001 | 0.0000 |

As is clear from Table 1, the measurement error is held to less than 0.1% by filter 860 or filter 865 only.

The filter coefficients of filter 860 and filter 865 are orthogonal to each other. Consequently, filter 860 and filter 865 can extract the vector components of the signal under test, that are, the in-phase component and the quadrature-phase component of the signal under test. Filter 860 and filter 865 measure the in-phase component and the quadrature-phase component of the signal under test when voltage signal E_{dut} has been selected and the in-phase component and the quadrature-phase component of the signal under test when voltage signal Eᵣᵣ has been selected.

Finally, CPU 750 measures the vector ratio of voltage signal E_{dut} and voltage signal Eᵣᵣ from the respective in-phase component and the quadrature-phase component.

Signal source 200 and local oscillator 820 are controlled by CPU 750 so that the difference in their oscillation frequencies becomes a pre-determined frequency. Moreover, the oscillation frequency of signal source 200 and local oscillator 820 changes in accordance with the frequency of the signals applied to device under test 400.

As previously described, depending on the selection of frequency fₘ of the measurement signal and frequency f_{IF} of the signal under test and the combined effect of low-pass filter 830 and filter 860 or filter 865, impedance measuring apparatus 600 can extract only the signal under test from the measurement signals and measure the in-phase component and the quadrature-phase component of this signal under test. In addition, the cut-off frequency f_{c} of low-pass filter 830 can be set at a higher frequency than in the past and therefore, high-speed measurement by impedance measuring apparatus 600 can be realized. Furthermore, the number of calculations for measuring the in-phase component and the quadrature-phase component is 15 when m=2 and therefore, even faster high-speed measurement by impedance measuring apparatus 600 is realized.

There are cases where frequency f_{IF} of the signal under test cannot be set so that it becomes 1/N of frequency fₘ of the measurement signal by controlling the specifications of the A/D converter that will be used, and the like, and it must be set at a frequency that is somewhat different from 1/N of frequency fₘ of the measurement signal. Even in this case, the above-mentioned high-speed effect is similarly obtained. An example is shown below:

For instance, frequency fₘ of the measurement signal is regarded as 30 kHz, frequency f_{LO} of the output signal of local oscillator 820 is regarded as 39.375 kHz, and frequency f_{IF} of the signal under test is regarded as 9.375 kHz. In this case, N is not an integer (N=3.2).

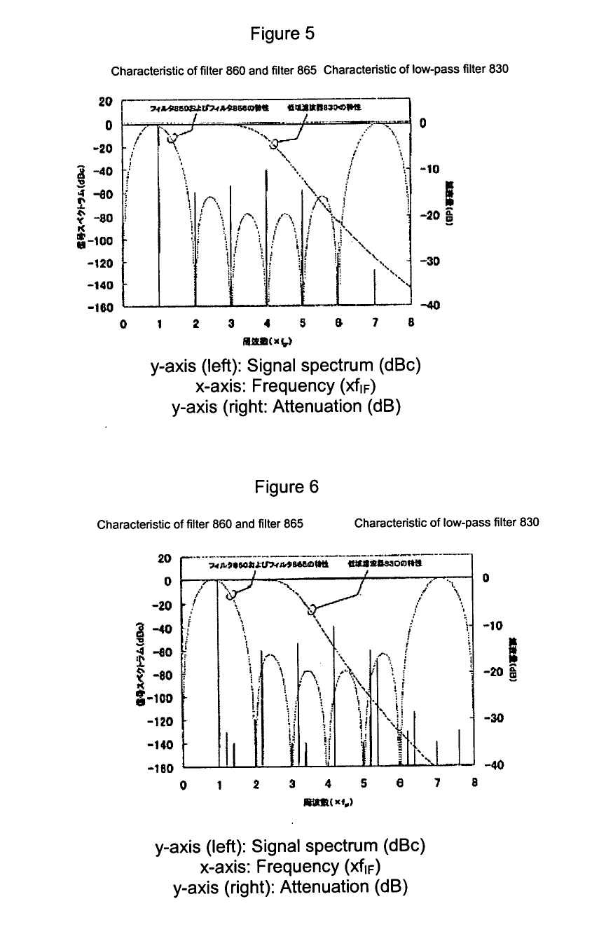

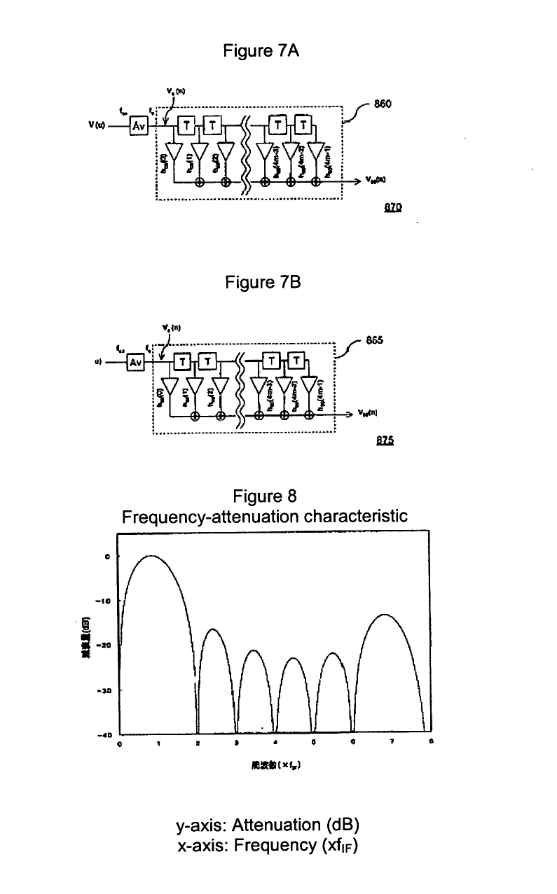

The spectrum of the output signals of mixer 810, the frequency-attenuation characteristic of low-pass filter 830, and the frequency-attenuation characteristic of filter 860 and filter 865 are shown in FIG. 6. The spectrum of the output signals of mixer 810 is given under almost the same conditions as in FIG. 5. However, frequency fₘ of the measurement signals is regarded as 30 kHz. In addition, frequency f_{LO} of the output signals of local oscillator 820 is regarded as 39.375 Hz.

The dotted curves in FIG. 6 show the frequency-attenuation characteristic of filter 860 and filter 865. Moreover, the dashed curve in FIG. 6 shows the frequency-attenuation characteristic of low-pass filter 830. The vertical solid lines in FIG. 6 show the spectrum of the output signal of mixer 810. The spectrum of the output signal of mixer 810 is normalized by frequency f_{IF} of the signal under test and the amplitude at the frequency f_{IF}. The y-axis on the left side in FIG. 6 shows the signal spectrum, the y-axis on the right side shows the attenuation, and the x-axis shows the frequency normalized by frequency f_{IF} of the signal under test. The output signals of mixer 810 contain unwanted signal components of various frequencies other than the frequency (f_{IF}) component of the signal under test. It is clear from FIG. 6 that these undesired signal components are attenuated by filter 860 or filter 865. When m=2, the unwanted signal component generated by mixer 810 is attenuated at least 15 dB by filter 860 or filter 865 as long as fₘ is a value from 1.7 f_{IF} to 7.3 f_{IF}.

Next, a table relating to measurement error is shown in Table 2. Table 2 shows the output signals of mixer 810, the attenuation of low-pass filter 830, the attenuation of filter 860 and filter 865, and the measurement error. Error 1 is the measurement error when the output signal of mixer 810 has been filtered by filter 860 or filter 865. Moreover, error 2 is the measurement error when the output signal of mixer 810 has been filtered by low-pass filter 830, as well as filter 860 or filter 865.

TABLE 2

| | | | | Low-pass filter | Filter 860 | | |
|---|---|---|---|---|---|---|---|
| Mixer 810 | | | | 830 (fc = 40 kHz) | Filter 865 | | |
| | Frequency | Ratio to | Output | Attenuation | Attenuation | Error 1 | Error 2 |
| Component | (kHz) | f_{IF} | (dBc) | (dB) | (dB) | (ppm) | (ppm) |
| f_{LO} − fₙ = f_{IF} | 9.375 | 1.00 | 0.00 | 0.00 | 0.00 | | |
| 3fₙ − 2f_{LO} | 11.250 | 1.20 | −130.00 | 0.00 | −1.20 | 0.26 | 0.28 |
| 7fₙ − 5f_{LO} | 13.125 | 1.40 | −140.00 | 0.00 | −3.55 | 0.07 | 0.07 |
| 2f_{LO} − 2fₙ | 18.750 | 2.00 | −120.00 | −0.03 | −317.72 | 0.00 | 0.00 |
| 2fₙ − f_{LO} | 20.625 | 2.20 | −60.00 | −0.10 | −18.39 | 120.33 | 119.00 |
| 3f_{LO} − 3fₙ | 28.125 | 3.00 | −140.00 | −3.29 | −353.15 | 0.00 | 0.00 |
| fₙ | 30.000 | 3.20 | −54.00 | −6.02 | −23.28 | 136.74 | 68.37 |
| 5fₙ − 3f_{LO} | 31.875 | 3.40 | −140.00 | −9.74 | −19.56 | 0.01 | 0.00 |
| f_{LO} | 39.375 | 4.20 | −40.00 | −28.87 | −24.26 | 613.08 | 22.60 |
| 5f_{LO} − 5fₙ | 46.875 | 5.00 | −140.00 | −46.56 | −353.15 | 0.00 | 0.00 |
| 2f_{LO} − fₙ | 48.750 | 5.20 | −60.00 | −50.63 | −21.91 | 80.24 | 0.24 |
| 3fₙ − f_{LO} | 50.625 | 5.40 | −70.00 | −54.55 | −16.78 | 45.79 | 0.09 |
| 3f_{LO} − 2fₙ | 58.125 | 6.20 | −130.00 | −68.94 | −14.48 | 0.06 | 0.00 |
| 2fₙ | 60.000 | 6.40 | −114.00 | −72.25 | −7.49 | 0.84 | 0.00 |
| 7f_{LO} − 7fₙ | 65.625 | 7.00 | −140.00 | −81.59 | 0.00 | 0.10 | 0.00 |
| 5fₙ − 2f_{LO} | 71.250 | 7.60 | −130.00 | −90.18 | −3.23 | 0.22 | 0.00 |

| | | | |
|---|---|---|---|
| Total error (ppm) | [symbol] (ppm) | 997.77 | 210.63 |
| Total error (%) | [symbol] (%) | 0.0998 | 0.0211 |

As is clear from Table 2, the measurement error is held to less than 0.1% by filter 860 or filter 865 only. Consequently, even though there are cases in which frequency f_{IF} of the signal under test must be set at a frequency that is somewhat different from 1/N of frequency fₘ of the measurement signal, measurement accuracy is not compromised and measurement is high-speed.

Recently, an over-sampling A/D converter has often been used for high-speed measurement. An over-sampling A/D converter is an A/D converter that samples at a frequency well exceeding the Nyquist frequency of input signal bandwidth and is characterized in that the dynamic range improves with an increase in the ratio of the sampling frequency to the Nyquist frequency. The over-sampling A/D converter samples at a clock frequency that is an x multiple of the Nyquist frequency and further performs filtering and noise shaping on the inside and then outputs the converted digital data.

Impedance measuring apparatus 200 of the first embodiment can be further improved when the above-mentioned type of high-speed A/D converter is used. An example is described below as a second embodiment of the present invention. Filter 860 and filter 865 of impedance measuring apparatus 600 are replaced with filter 870 and filter 875. Moreover, filter 870 and filter 875 have an averaging device Av in front of filter 860 and filter 865. The sampling frequency of the A/D converter of the impedance measuring apparatus of the second embodiment is changed to fₛₓ.

fₛ_{ₓ}=(4m·x)·f_{IF}

By means of the second embodiment, every x number of data V(u) that have been sampled at sampling frequency fₛₓ are averaged in succession and these averaged data Vₐ(n) are filtered. Filter 870 and filter 875 have the response characteristics represented by the following formulas as a result of averaging and the effects of filter coefficients hₒₒ(k) and h₉₀(k).

$${V}_{oo} ( n ) = {\sum }_{k = 0}^{4 m - 1} {h}_{oo} ( k ) \cdot {V}_{a} ( n - k )$$

$${V}_{90} ( n ) = {\sum }_{k = 0}^{4 m - 1} {h}_{90} ( k ) \cdot {V}_{a} ( n - k )$$

Filters 870 and 875 have the same frequency-attenuation characteristic. The frequency-attenuation characteristic of filter 870 and filter 875 when m=2 and x=2 is shown in FIG. 8. It is clear from FIG. 8 that filter 870 and filter 875 have an obvious attenuation characteristic near the frequency that corresponds to the higher harmonic component of the signal under test. Furthermore, it is clear that it has an obvious attenuation characteristic, even at the passband that appears on the higher harmonic side in FIG. 4 and that the filter characteristics are improved. Filter 870 and filter 875 have an obvious attenuation characteristic near the frequency that corresponds to the higher harmonic component of the signal under test, even in cases other than m=2.

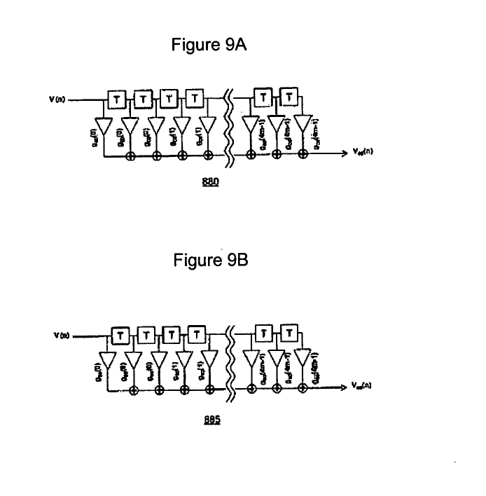

The impedance measuring apparatus of the second embodiment can also use filter 880 and filter 885 in place of filter 870 and filter 875. The internal block of filter 880 and filter 885 here are shown in FIG. 9. Filter 880 and filter 885 are similar to filter 860 and filter 865, but they differ in that an x number of the same filter coefficient are connected. Filter 880 and filter 885 have the response characteristics represented by the following formula as a result of the effects of filter coefficients gₒₒ(k) and g₉₀(k).

$${V}_{oo} ( n ) = {\sum }_{k = 0}^{4 m - 1} {\sum }_{j = 0}^{x - 1} {g}_{oo} ( k ) \cdot V ( n - x \cdot k - j )$$

$${V}_{90} ( n ) = {\sum }_{k = 0}^{4 m - 1} {\sum }_{j = 0}^{x - 1} {g}_{90} ( k ) \cdot V ( n - x \cdot k - j )$$

$$Wherein , \\ {g}_{oo} ( k ) = \frac{sin ( \frac{π}{2 m} j + θ )}{2 mx}$$

$${g}_{90} ( k ) = \frac{cos ( \frac{π}{2 m} j + θ )}{2 mx}$$

Incidentally, θ is any value. The frequency-attenuation characteristic of filter 880 and filter 885 is the same as when filter 870 and filter 875 are used and is as shown in FIG. 8.

As previously described in detail, a vector-detecting apparatus that detects the in-phase component and the quadrature-phase component of a pre-determined frequency signal comprises a first filtration means and a second filtration means, the impulse response of this first filtration means is weighted by the sine function of the same frequency as the pre-determined frequency, the second filtration means is weighted by the cosine function of the same frequency as the above-mentioned pre-determined frequency, the output of the first filtration means is regarded as the in-phase component of the above-mentioned frequency signal, and the output of the second filtration means is regarded as the quadrature-phase component of the above-mentioned pre-determined frequency signal and therefore, high-speed vector measurement of the measurement signal can be realized.

Moreover, when a frequency converter is set up in the vector-detecting apparatus, the ratio of the frequency before conversion by the frequency converter and the frequency after conversion is an integer of 2 or higher and the output signals of the frequency converter are input to the first filtration means and the second filtration means. Therefore, the band of the low-pass filter that is in back of the frequency converter can be expanded and as a result, high-precision, high-speed vector detection of the measurement signals can be realized.

Furthermore, the first filtration means and the second filtration means are FIR filters and therefore, for instance, processing can be easily realized by FPGA and the like, and a DSP is not necessary. Therefore, cost reduction, energy conservation, and space conservation of the vector-detecting apparatus are possible.

What is claimed is:

1. A vector-detecting apparatus that detects the in-phase component and the quadrature-phase component of a pre-determined frequency signal, said apparatus comprising:
a first filter; and
a second filter whose impulse response is orthogonal to said first filter,
wherein the output of said first filter is regarded as the in-phase component of said pre-determined frequency signal, and output of said second filter is regarded as the quadrature-phase component of said pre-determined frequency signal.

2. The vector-detecting apparatus according to claim 1, wherein the impulse response of said first filter is weighted by the sine function of the same frequency as the pre-determined frequency signal and the impulse response of said second filter is weighted by the cosine function of the same frequency as the pre-determined frequency signal.

3. A vector-detecting apparatus that detects the in-phase component and the quadrature-phase component of a pre-determined frequency signal, said apparatus comprising:
a frequency converter;
a first filter; and
a second filter,
wherein said first and second filters filter the output signal of said frequency converter and whose impulse responses are orthogonal to each other, and wherein the output of said first filter is regarded as the in-phase component of said pre-determined frequency signal, and the output of said second filter is regarded as the quadrature-phase component of said pre-determined frequency signal.

4. The vector-detecting apparatus according to claim 3, wherein the impulse response of said first filter is weighted by the sine function of the same frequency as said pre-determined frequency signal after frequency conversion by said frequency converter, and the impulse response of said second filter is weighted by the cosine function of the same frequency of the same pre-determined frequency signal after frequency conversion by the frequency converter.

5. The vector-detecting apparatus according to claim 3, wherein the ratio of the frequency of said pre-determined frequency signal before conversion by said frequency converter and the frequency after conversion by said frequency converter is an integer of 2 or higher.

6. An impedance measuring apparatus comprising a vector-detecting apparatus, wherein said vector-detecting apparatus comprises:
a first filter and a second filter whose impulse responses are orthogonal to each other;
wherein the output of said first filter is regarded as the in-phase component of said pre-determined frequency signals, and the output of said second filter is regarded as the quadrature-phase component of said pre-determined frequency signal.

7. The impedance measuring apparatus according to claim 6, wherein the impulse response of said first filter is weighted by the sine function of the same frequency as the pre-determined frequency signal and the impulse response of said second filter is weighted by the cosine function of the same frequency of the pre-determined frequency signal.

8. An impedance measuring apparatus that measures the in-phase component and the quadrature-phase component of a pre-determined frequency signal, said apparatus comprising:
a frequency converter;
a first filter; and
a second filter, wherein said first and second filters are capable of filtering the output signal of said frequency converter and whose impulse responses are orthogonal to each other,
wherein the output of said first filter is regarded as the in-phase component of said pre-determined frequency signal, and the output of said second filter is regarded as the quadrature-phase component of said pre-determined frequency signal.

9. The impedance measuring apparatus according to claim 8, wherein the impulse response of said first filter is weighted by the sine function of the same frequency as the pre-determined frequency signal after frequency conversion by said frequency converter and the impulse response of said second filter is weighted by the cosine function of the same frequency as the pre-determined frequency signal after frequency conversion by said frequency converter.

10. The impedance measuring apparatus according to claim 8, wherein the ratio of the frequency of said pre-determined frequency signal before conversion by said frequency converter and the frequency after conversion by said frequency converter is an integer of 2 or higher.
